(19) United States
(12) Patent Application Publication
(10) Pub. No.: US 2008/0067554 A1
(43) Pub. Date: Mar. 20, 2008

(54) NAND flash memory device with 3-dimensionally arranged memory cell transistors

(76) Inventors: Jae-Hun Jeong, Suwon-si (KR); Ki-Nam Kim, Seoul (KR); Soon-Moon Jung, Yongin-si (KR); Jae-Hoon Jang, Seongnam-si (KR)

Correspondence Address: LEE & MORSE, P.C., 3141 FAIRVIEW PARK DRIVE, SUITE 500, FALLS CHURCH, VA, 22042, US

(21) Appl. No.: 11/705,163

(22) Filed: Feb. 12, 2007

(30) Foreign Application Priority Data
Sep. 14, 2006 (KR) 2006-89327
Nov. 27, 2006 (KR) 2006-117759

(51) Int. Cl. H01L 29/76

(52) U.S. Cl. 257/211; 257/E21.689

(57) ABSTRACT

A NAND flash memory device includes a plurality of stacked semiconductor layers, device isolation layer patterns disposed in predetermined regions of each of the plurality of semiconductor layers, the device isolation layers defining active regions, source and drain impurity regions in the active regions, a source line plug structure electrically connecting the source impurity regions, and a bit-line plug structure electrically connecting the drain impurity regions, wherein the source impurity regions are electrically connected to the semiconductor layers.

### BACKGROUND OF THE INVENTION

1. Field of the Invention

The present invention relates to a semiconductor device. More particularly, the present invention relates to a NAND flash memory device with 3-dimensionally arranged memory cell transistors.

2. Description of the Related Art

Electronic products such as computers, mobile phones, multimedia players, digital cameras, etc., may include semiconductor devices such as a memory chip for storing information and a processing chip for controlling information. The semiconductor devices may include electronic elements such as a transistor, a resistor, a capacitor, etc. Electronic elements may be integrated on a semiconductor substrate, and there may be a demand for a high level of integration in order to provide the high performance and reasonable price that consumers have come to demand.

In order to achieve high levels of integration, advanced processing technologies such as a photolithography process may be required in the manufacturing process for the semiconductor device. However, advanced processing technologies may be immensely expensive and time consuming to develop, thus limiting advances in the degree of integration.

Semiconductor devices with transistors arranged in 3-dimensions have been proposed as one way to advance the degree of integration. Manufacturing of semiconductor device having a 3-dimensional transistor structure may include forming one or more single-crystalline semiconductor layer on a semiconductor substrate such as a wafer, where the single-crystalline semiconductor layers may be formed using, e.g., epitaxial technology. The single-crystalline semiconductor layers may thus be used to form transistors on multiple layers of a device.

Through-plugs, which pass through one or more of the semiconductor layers, may be needed to connect the 3-dimensionally arranged transistors. A first type of through-plug directly contacts the semiconductor layer. A second type of through-plug is separated from the semiconductor layer by a predetermined insulating layer, e.g., an interlayer dielectric (ILD) layer. In the case of the second type through-plug, the semiconductor layers may have a gap region filled with an interlayer dielectric layer which the through-plug passes through. However, the presence of the gap region lowers the degree of integration of the semiconductor device.

The first type through-plug may directly contact the semiconductor layer, and thus may be electrically connected to the corresponding semiconductor layer, allowing a higher degree of integration. For example, a first type through-plug connected to a source/drain impurity region of a transistor may directly contact a semiconductor layer under the source/drain region. However, the conductivity type of the source/drain impurity region may be different from that of the semiconductor layer, and thus the contact between the through-plug and the semiconductor layer could cause an electric failure of the semiconductor device. Therefore, in general, the first type through-plug may be a doped silicon having a conductivity type that is the same as that of the source/drain impurity region and different from that of the semiconductor layer. In this case, the first type through-plug and the semiconductor layer constitute a diode, allowing the first type through-plug to be connected to the source/drain impurity region.

In the structure just described, the doped silicon has a resistivity higher than that of comparable metallic materials, which may cause technical problems such as a low operating speed, high power consumption, etc. For example, where a through-plug that is formed of doped silicon contacts a common source line of a NAND flash memory device, a cell current decrease may be caused by the body effect of a ground selection line.

In the conventional NAND flash memory device, electric potentials of the semiconductor layer and the semiconductor substrate must be controlled independently because a memory cell is programmed or erased using FN tunneling. To this end, separate through-plugs, or well-plugs, contacting the semiconductor substrate or the semiconductor layer(s) may be needed. The need for the separate well-plugs may decrease the degree of integration degree of a NAND flash memory device, and may make manufacturing the NAND flash memory device more complicated.

### SUMMARY OF THE INVENTION

The present invention is therefore directed to a NAND flash memory device with 3-dimensionally arranged memory cell transistors, which substantially overcomes one or more of the problems due to the limitations and disadvantages of the related art.

It is therefore a feature of an embodiment of the present invention to provide a 3-dimensional NAND flash memory device including through-plugs of reduced resistivity.

It is therefore another feature of an embodiment of the present invention to provide a 3-dimensional NAND flash memory device without separate well-plugs.

At least one of the above and other features and advantages of the present invention may be realized by providing a NAND flash memory device, including a plurality of stacked semiconductor layers, device isolation layer patterns disposed in predetermined regions of each of the plurality of semiconductor layers, the device isolation layers defining active regions, source and drain impurity regions in the active regions, a source line plug structure electrically connecting the source impurity regions, and a bit-line plug structure electrically connecting the drain impurity regions, wherein the source impurity regions are electrically connected to the semiconductor layers.

The source line plug structure may be in ohmic contact with the source impurity regions and at least one of the plurality of semiconductor layers. The source line plug structure may include at least one metallic material. The source line plug structure may include a metal plug passing through at least one of the plurality of semiconductor layers and at least one of the source impurity regions, and a barrier metal layer formed at least at a sidewall of the metal plug, the barrier metal layer directly contacting the at least one semiconductor layer and the at least one source impurity region.

The source line plug structure may pass through at least one of the plurality semiconductor layers and at least one of the source impurity regions.

The plurality of stacked semiconductor layers may include a lower semiconductor layer, the lower semiconductor layer being a single-crystalline semiconductor wafer, and at least one upper semiconductor layer stacked on the lower semiconductor layer, wherein the source line plug structure may pass through the upper semiconductor layer and source impurity regions of the upper semiconductor layer, the source line plug structure being connected to source impurity regions of the lower semiconductor layer.

The source line plug structure may pass through the source impurity regions of the lower semiconductor layer and may be electrically connected to the lower semiconductor layer. The device may further include an ohmic doped region disposed under the source impurity region of the lower semiconductor layer such that the lower semiconductor layer and the source line plug structure are in ohmic contact, wherein the ohmic doped region may have a different conductivity type from that of the source and drain impurity regions.

The bit-line plug structure may pass through the upper semiconductor layer and the drain impurity regions of the upper semiconductor layer and may be connected to the drain impurity regions of the lower semiconductor layer, and the bit-line plug structure may be formed of silicon having a conductivity type that is the same as that of the source and drain impurity regions and different from that of the semiconductor layers. A device isolation layer pattern in the upper semiconductor layer may pass through the upper semiconductor layer.

The device may further include a gate structure disposed between the bit-line plug structure and the source line plug structure, the gate structure crossing the active regions of each of the semiconductor layers, bit lines crossing the gate structure, the bit lines connected to the drain impurity regions by the bit-line plug structure, and a common source line connected to the source impurity regions by the source line plug structure, wherein the gate structure may include a string selection line adjacent to the bit-line plug structure, a ground selection line adjacent to the source line plug structure, and a plurality of word lines between the string selection line and the ground selection line.

The string selection line, the ground selection line and the word lines formed on each of the semiconductor layers, and the bit lines, may be configured to selectively access at least one memory cell of the corresponding semiconductor layer, and the device may be configured to program a memory cell selected by a predetermined bit line and a predetermined word line of a predetermined semiconductor layer by applying one of a ground voltage and a positive power voltage to the common source line.

The device may be further configured to program the selected memory cell by applying an accumulation voltage to the ground selection line, the accumulation voltage allowing an active region under the ground selection line to be in an accumulation state. The accumulation voltage may be within a range of about a negative power voltage to about 0 volts. The device may be configured to erase a memory cell of a predetermined semiconductor layer by applying an erase voltage to the common source line.

The plurality of stacked semiconductor layers may include a lower semiconductor layer and an upper semiconductor layer that are sequentially stacked, the gate structure may include lower word lines and upper word lines disposed on the lower and upper semiconductor layers, respectively, lower gate contact plugs and upper gate contact plugs may be connected to the lower and upper word lines, respectively, and the upper word lines may be offset from the lower word lines, such that the lower gate contact plug is separated from the upper word lines.

The upper semiconductor layer may have a gate aperture passing through the upper semiconductor layer, wherein the gate aperture includes a region in which the lower gate contact plug is disposed. The lower and upper gate contact plugs may include at least one metallic material. The lower and upper gate contact plugs may be silicon having a different conductivity type from that of the source and drain impurity regions. A lower word line and an upper word line may be equipotential during operation of the device.

The bit-line plug structure may be silicon having a conductivity type that is the same as that of the impurity regions and different from that of the semiconductor layers. The device may further include an ohmic doped region in at least one of the semiconductor layers, the ohmic doped region electrically contacting the source line plug structure and having a different conductivity type from that of the source and drain impurity regions. The source impurity regions may be equipotential with the semiconductor layers during operation of the device.

### BRIEF DESCRIPTION OF THE DRAWINGS

The above and other features and advantages of the present invention will become more apparent to those of ordinary skill in the art by describing in detail exemplary embodiments thereof with reference to the attached drawings, in which:

FIGS. 1 through 4 illustrate schematic perspective views of a NAND flash memory device with 3-dimensionally arranged memory cell transistors according to an embodiment of the present invention;

FIGS. 5 through 8 illustrate cross-sectional views of a structure of through-plugs of a NAND flash memory device with 3-dimensionally arranged memory cell transistors according to an embodiment of the present invention;

FIGS. 9A and 9B illustrate cross-sectional views of through-plug structures of a NAND flash memory device according to other embodiments of the present invention; and

FIGS. 10A through 10C illustrate cross-sectional views of a NAND flash memory device according to additional embodiments of the present invention.

### DETAILED DESCRIPTION OF THE INVENTION

Korean Patent Application No. 2006-89327, filed on Sep. 14, 2006, and No. 2006-117759, filed on Nov. 27, 2006, in the Korean Intellectual Property Office, both of which are entitled: “NAND Flash Memory Device with 3-Dimensionally Arranged Memory Cell Transistors,” are incorporated by reference herein in their entirety.

The present invention will now be described more fully hereinafter with reference to the accompanying drawings, in which exemplary embodiments of the invention are illustrated. The invention may, however, be embodied in different forms and should not be construed as limited to the embodiments set forth herein. Rather, these embodiments are provided so that this disclosure will be thorough and complete, and will fully convey the scope of the invention to those skilled in the art.

It will be understood that terms such as “first” and “second” may be used herein to describe various regions, layers and/or sections. These terms are used to distinguish one region, layer and/or section from another region, layer and/or section. However, these regions, layers and/or sections should not be limited by these terms. In the figures, the dimensions of layers and regions may be exaggerated for clarity of illustration. It will also be understood that when a layer or element is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals refer to like elements throughout.

Embodiments of the present invention will be described using a NAND flash memory device having a 3-dimensional arrangement of memory cells as a particular example. Additionally, for the clarity, only two semiconductor layers will be described. However, it will be appreciated that the present invention is not limited to these particular examples, and that other types of devices and other numbers of layers may be implemented.

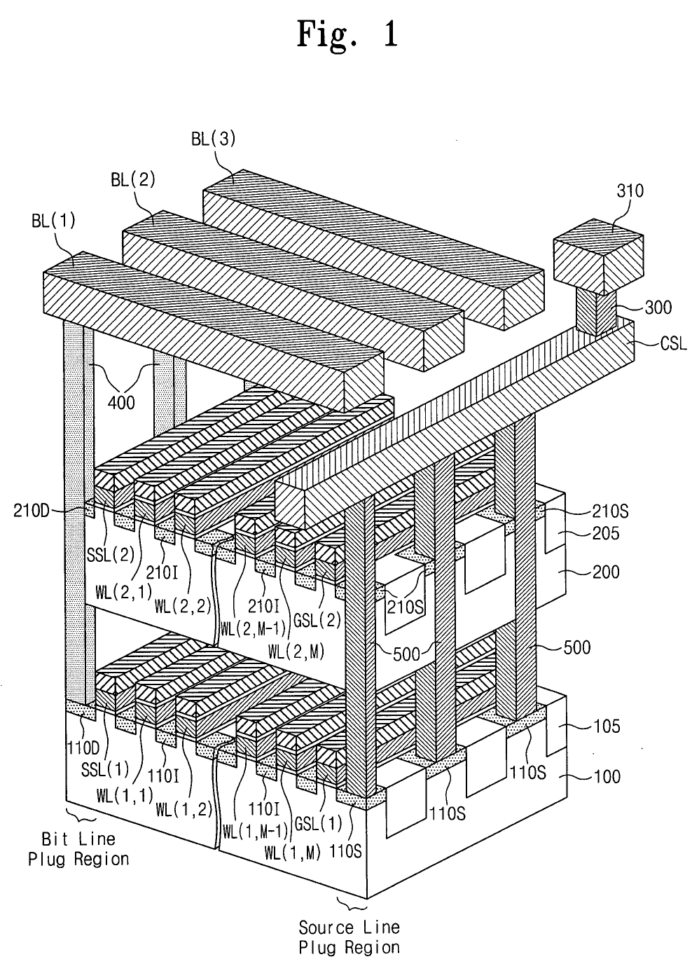

FIGS. 1 through 4 illustrate schematic perspective views of a NAND flash memory device with 3-dimensionally arranged memory cell transistors according to an embodiment of the present invention, in which source plugs may electrically connect source regions to semiconductor layers in a stack of semiconductor layers.

Referring to FIGS. 1-4, the device may include a first semiconductor layer 100 and a second semiconductor layer 200. The first semiconductor layer 100 may be, e.g., a single-crystalline silicon wafer, and the second semiconductor layer 200 may be, e.g., an epitaxial layer, i.e., a single crystalline silicon epitaxial layer that is formed through an epitaxial process using the first semiconductor layer 100 as a seed layer. Korean Patent Application No. 2004-97003, the disclosure of which is incorporated by reference herein in its entirety, and a corresponding application of which was filed in the U.S. Patent and Trademark Office on Nov. 5, 2005, as U.S. patent application Ser. No. 11/286,501, discloses a method of forming an epitaxial semiconductor layer on a semiconductor wafer using an epitaxial process. The semiconductor layers 100 and 200 may have memory cell arrays with substantially the same structure, and thus the memory cells may form multi-layered cell arrays.

For clarity, various elements of the cell arrays may be identified by parenthetical reference to the corresponding semiconductor layer. Thus, a ground selection line on the first semiconductor layer may be referred to as a ground selection line GSL(1). Similarly, a string selection line on the second semiconductor layer may be referred to as the string selection line SSL(2).

Additionally, where a plurality of elements is disposed on a particular layer, the parenthetical reference may include another identifying element. For example, a plurality of word lines WL may be disposed on a semiconductor layer. An a^{th} word line WL disposed on the second semiconductor layer 200 may be referred to as a word line WL(2, a). Also, where the parenthetical reference need not refer to a particular semiconductor layer, the element for the semiconductor layer may be omitted. For example, a c^{th} bit line BL may be referred to as a bit line BL(c).

Each of the semiconductor layers 100 and 200 may include active regions defined by device isolation layer patterns 105. The active regions may be arranged in parallel to one another and may extend in a first direction. The device isolation layer patterns 105 may be formed of insulating materials, e.g., silicon oxide, and may electrically isolate the active regions.

A gate structure including a pair of gate selection and string selection lines GSL and SSL, as well as m word lines WL, may be disposed on each of the semiconductor layers 100 and 200, where m is a positive integer. In an implementation, m may be a multiple of eight. Source plugs 500 may be disposed at one side of the gate structure, and bit-line plugs 400 may be disposed at the other side of the gate structure. The bit-line plugs 400 may be connected to respective bit lines BL that cross the word lines WL. There may be n bit lines BL, where n is a positive integer. In an implementation, n may be a multiple of eight. The bit lines BL may cross the word lines WL on the uppermost semiconductor layer, e.g., on the second semiconductor layer 200 in FIG. 1.

The word lines WL may be disposed between the gate selection line GSL and the string selection line SSL. One of the gate selection line GSL and the string selection line SSL may be configured as a ground selection line GSL controlling an electric connection between a common source line CSL and memory cells. Another one of the gate selection line GSL and the string selection line SSL may be configured as a string selection line SSL controlling electric connection between bit lines BL and the memory cells.

Impurity regions may be formed in the active regions between the gate and string selection lines GSL and SSL and the word lines WL. In particular, impurity regions 110S and 210S alongside respective ground selection lines GSL(1) and GSL(2) may be source impurity regions that are connected to the common source line CSL through the source plugs 500. Hereinafter, the impurity regions 110S and 210S will be referred to as first and second source impurity regions 110S and 210S, respectively, and impurity regions 110D and 210D will be referred to as first and second drain impurity regions 110D and 210D, respectively.

Drain impurity regions 110D and 210D alongside respective string selection lines SSL(1) and SSL(2) may be drain regions that are connected to the bit lines BL through the bit-line plugs 400. Internal impurity regions 110I and 210I may also be formed between the word lines WL themselves, i.e., along opposite sides of the word lines WL. The internal impurity regions 110I and 210I may connect the memory cells in series.

The source plugs 500 may extend between the first and second semiconductor layers 100 and 200, and may electrically connect the first and second source regions 110S and 210S, which may be used as the source electrodes, to the first and second semiconductor layers 100 and 200. The first and second source regions 110S and 210S may be equipotential with the semiconductor layers 100 and 200.

In an implementation, as illustrated in FIGS. 1 through 3, the source plugs 500 may pass through the second semiconductor layer 200 and the second source regions 210S, and may be connected to the first source regions 110S. Each of the source plugs 500 may directly contact inner regions of the second semiconductor layer 200 and the second source region 210S.

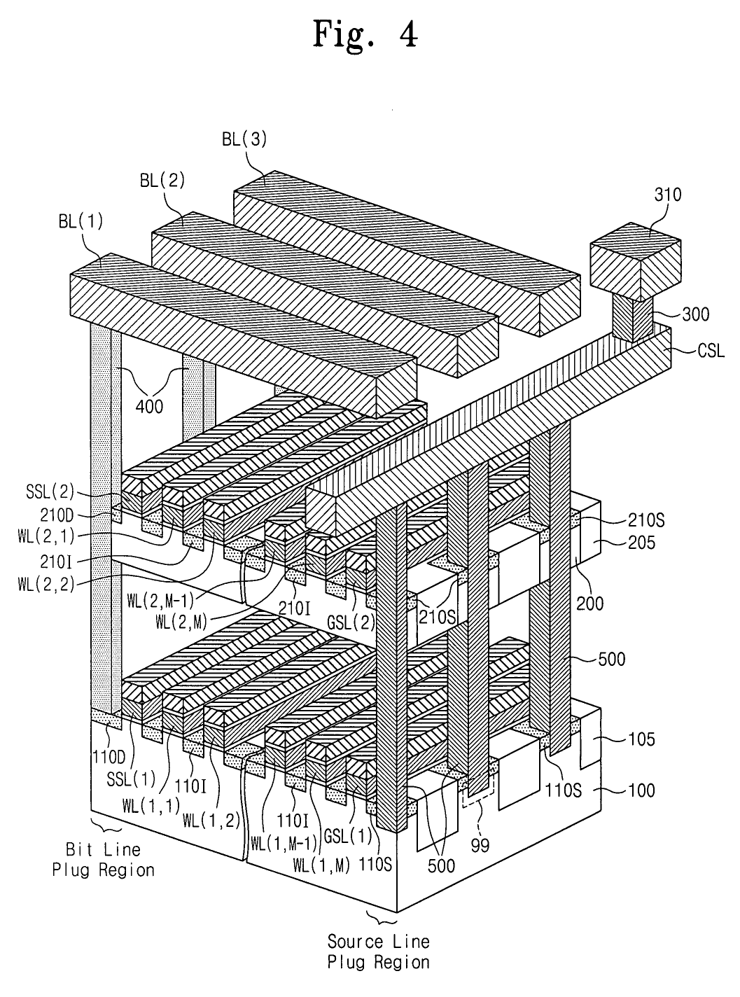

In an implementation, as illustrated in FIG. 4, each of the source plugs 500 may be connected to the first semiconductor layer 100 by passing through the second semiconductor layer 200, the second source region 210S, and the first source region 110S. In this case, the source plug 500 may directly contact inner regions of the second semiconductor layer 200, the second source region 210S, and the first source region 110S, and may be inserted to a predetermined depth into the first semiconductor layer 100, as identified by a dashed box 99 in FIG. 4. This may provide a more stable contact with the first semiconductor layer 100.

The source plug 500 may include one or more metallic materials. The source plug 500 may be formed of, e.g., one or more of copper, aluminum, tungsten, titanium, tantalum, titanium nitride, tantalum nitride, tungsten nitride, etc. The use of a metallic material for the source plug 500 may help avoid some of the problems in the conventional art that are caused by the high resistivity of doped silicon, such as a low operation speed, high power consumption, decreased cell current, etc.

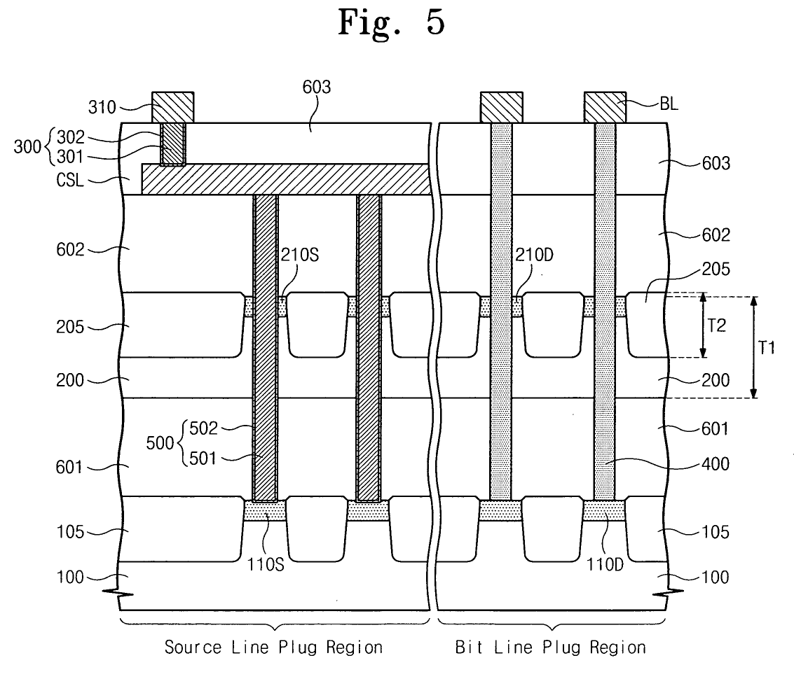

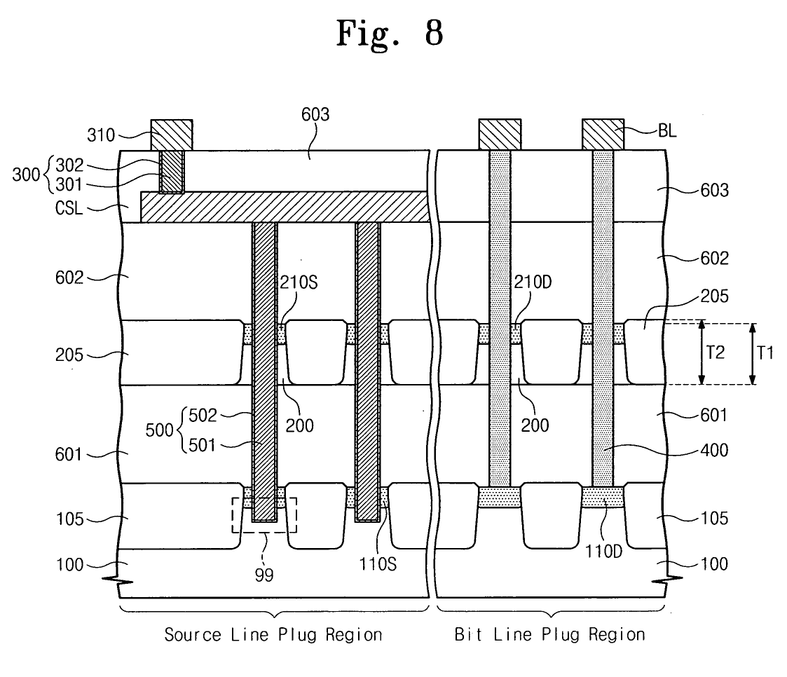

As is well known, when a metallic material contacts a semiconductor, a short-key junction accompanied by rectification may be formed. To prevent this phenomenon, as illustrated in FIGS. 5, 7 and 8, the source plug 500 according to the present invention may include a metal plug 501 that passes through the semiconductor layer 200, the second source region 210S and/or the first source region 110S, and a barrier metal layer 502 that allows ohmic contact with the semiconductor layers 110 and 200, and/or the first and second source regions 110S and 210S. The barrier metal layer 502 may be one or more of titanium, tantalum, titanium nitride, tantalum nitride, and tungsten nitride.

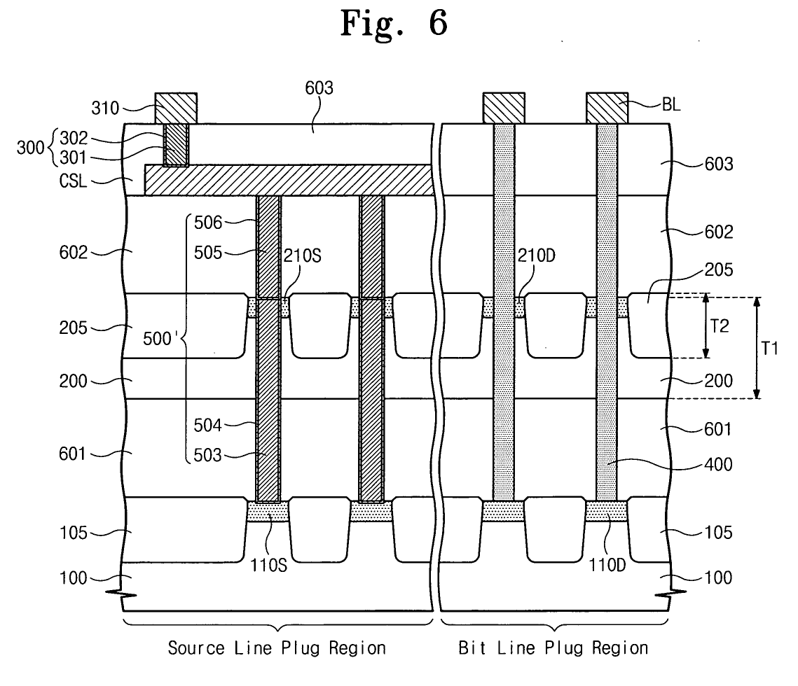

Referring to FIG. 6, in another implementation, a source plug 500′ may include a plurality of source plugs that are sequentially stacked. In detail, the source plug 500′ may include a first metal plug 503 disposed on the first semiconductor layer 100, a first barrier metal layer 504 surrounding the first metal plug 503, a second metal plug 505 disposed on the second semiconductor layer 200, and a second barrier metal layer 506 surrounding the second metal plug 505. Of course, the location and/or structure of the boundary between the first metal plug 503 and the second metal plug 505 may vary. For example, the boundary may be between the first semiconductor layer 100 and the second semiconductor layer 200 (not shown). In another implementation (not shown), a pad structure for stable connection may be further interposed between the first metal plug 503 and the second metal plug 505.

As illustrated in FIGS. 1 through 8, the source plugs 500 may be connected to a common source line CSL that extends in a direction crossing the active regions. Consequently, the semiconductor layers 100 and 200, and the first and second source regions 110S and 210S, may all be equipotential with the equipotential with the common source line CSL due to the connections provided by the source plugs 500.

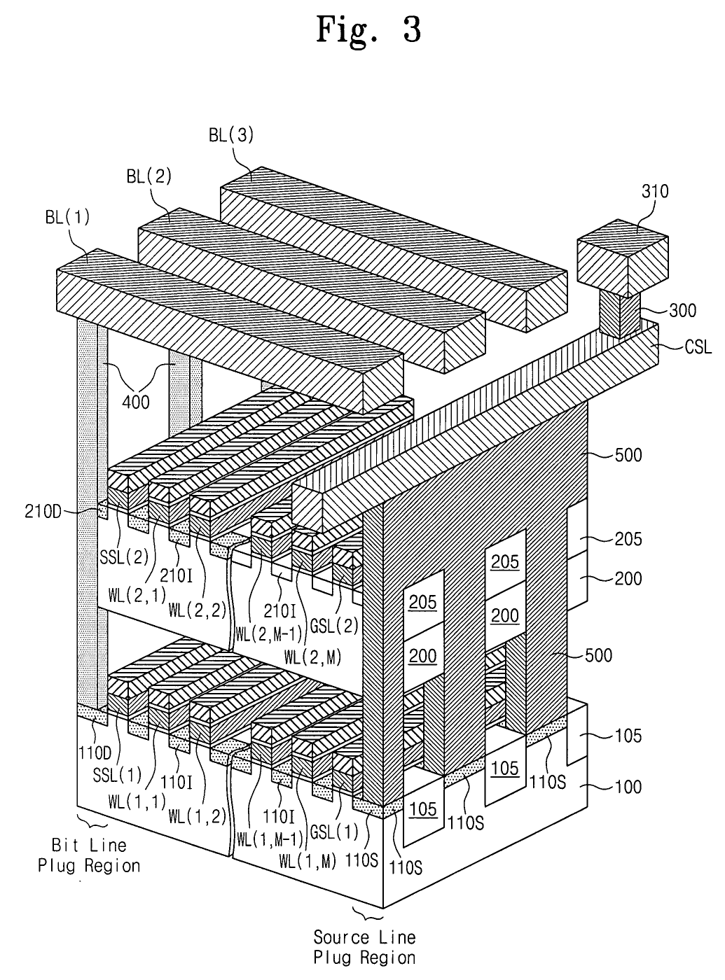

According to another embodiment of the present invention, as illustrated in FIG. 3, the source plug 500 may have a linear portion that crosses the active regions on the uppermost semiconductor layer, i.e., on the second semiconductor layer 200. In this case, forming of the source plug 500 may include patterning a second interlayer dielectric layer, e.g., layer 602 in FIGS. 5 through 8, that covers the second semiconductor layer 200, in order to form an upper aperture crossing the active regions and exposing the second source regions 210S and the second device isolation layer patterns 205. An upper region of the source plug 500 may function as the common source line CSL, such that a separately-formed common source line CSL may not be required.

Also, as illustrated in FIG. 3, after the upper aperture is formed, another, lower aperture may be formed for defining a portion of the lower region of the source plug 500. The lower aperture may be formed using, e.g., the second device isolation layer pattern 205 as an etch mask. Once formed, the corresponding portion of the lower region of the source plug 500 may pass through the second semiconductor layer 200 and the second source region 210S and may have the same width as the active region.

Turning now to the structure of the bit-line plugs 400, the bit-line plugs 400 may have the structures corresponding to either of the conventional through-plugs, i.e., the first and second type through-plugs described above. As illustrated in FIGS. 1 through 8, the bit-line plug 400 may pass through the second semiconductor layer 200 and the second drain region 210D to serve as a drain electrode. The bit-line plug 400 may be formed of, e.g., doped silicon having a conductivity type which is the same as that of the impurity regions and different from that of the semiconductor layers.

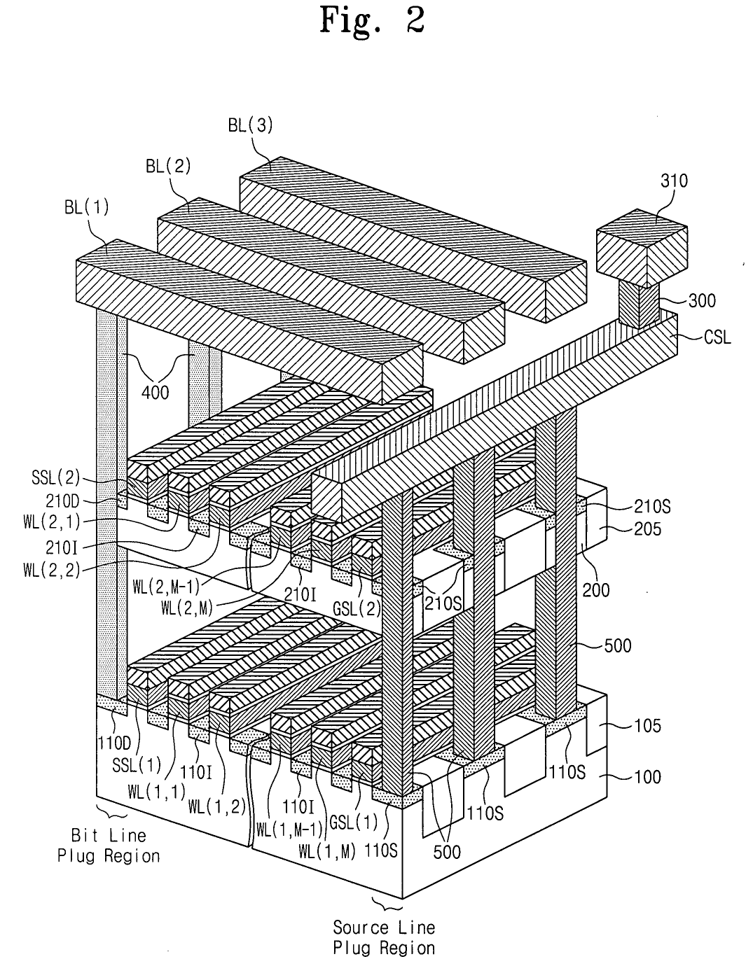

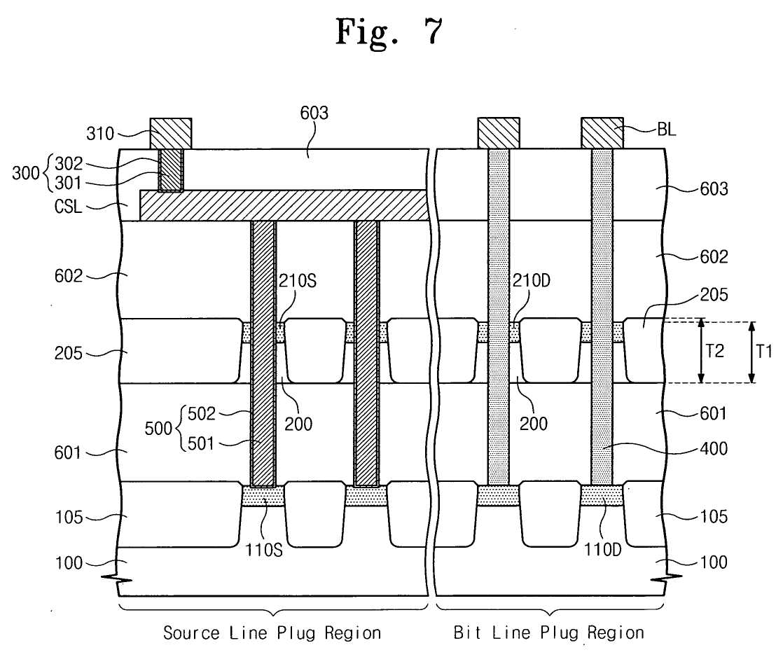

In an embodiment of the present invention, the relative thickness of the semiconductor layers and the device isolation layers may be varied. For example, comparing FIGS. 5 and 7, a thickness T1 of a semiconductor layer other than the lowermost semiconductor layer, e.g., the second semiconductor layer 200, may be less than a thickness T2 of the corresponding device isolation layer patterns, e.g., the second device isolation layer patterns 205, formed therein. Various examples of this configuration are illustrated in FIGS. 2, 4, 7 and 8. Thus, the second device isolation layer pattern 205 may pass through or penetrate the second semiconductor layer 200.

In the example just described, active regions of the second semiconductor layer 200 may be isolated by the second device isolation layer patterns 205. Accordingly, since the source plugs 500 may be electrically connected to the second semiconductor layer 200, the potential of the second semiconductor layer 200 may be controlled by the source plugs 500.

In an embodiment of the present invention, the common source line CSL may be connected to a source line 310 through an upper plug 300. The source line 310 may be formed simultaneously with the bit lines BL, and may be formed of substantially the same material and have substantially the same thickness as the bit lines BL. The upper plug 300 may include an upper metal plug 301 and an upper barrier metal layer 302.

The NAND flash memory device according to an embodiment of the present invention may be programmed under the program voltage conditions set forth in Tables 1, 2 and 3 below, and may be erased under the erase voltage conditions set forth in Table 4 below.

TABLE 1

| | Present invention (V) | Conventional art 1 |
|---|---|---|
| Selected word line | V_{PGM} | V_{PGM} |
| Unselected word line | V_{PASS} | V_{PASS} |
| Selected bit line | 0 | 0 |
| Unselected bit line | V_{CC} | V_{CC} |
| String selection line | V_{CC} | V_{CC} |
| Ground selection line | 0 | 0 |
| Common source line | 0 | 0 |
| Semiconductor layer | 0 | 0 |

TABLE 2

| | Present invention (V) | Conventional art 2 |
|---|---|---|
| Selected word line | V_{PGM} | V_{PGM} |
| Unselected word line | V_{PASS} | V_{PASS} |
| Selected bit line | 0 | 0 |
| Unselected bit line | V_{CC} | V_{CC} |
| String selection line | V_{CC} | V_{CC} |
| Ground selection line | −V_{CC} | 0 |
| Common source line | 0 | 1.5 |
| Semiconductor layer | 0 | 0 |

As described above, in a NAND flash memory device according to the present invention, the common source line CSL may be equipotential with the semiconductor layers 100 and 200. Thus, as shown in Tables 1 and 2, a voltage applied to the common source line CSL may likewise be applied to the semiconductor layers 100 and 200. The programming operation may use FN tunneling according to a voltage difference between a selected word line and a selected bit line. Thus, even though the common source line CSL and the semiconductor layers 100 and 200 are equipotential, a memory cell may be conventionally programmed, as shown in Table 1.

In a conventional programming method, Vcc may be applied to the string selection line SSL to selectively program a memory cell selected by a selected word line WL and a selected bit line BL, while a current path to the common source line CSL may be blocked by applying 0 volts to the ground selection line GSL. Referring to Table 2, a leakage current caused by self-boosting, which may cause the leakage current to flow through the common source line CSL from the unselected active region, may be controlled by applying a voltage of 1.5 V to the common source line CSL, in order to block a current path to the common source line CSL from an unselected active region.

A NAND flash memory device according to an embodiment of the present invention may be configured to be programmed through the application of a predetermined accumulation voltage to the ground selection line GSL, in order to minimize the leakage current caused by self-boosting. An active region under the ground selection line GSL may be placed in an accumulation state by the accumulation voltage, and, thus, the leakage current to the common source line CSL from an unselected active region may be cut off. As the leakage current is cut off, a voltage difference between an unselected active region and a selected word line may decrease, so that undesired programming of an unselected memory cell may be prevented. In an implementation, the NAND flash memory device may be configured to receive an accumulation voltage within a range of about a negative power voltage (−V_{CC}) to about 0 V.

TABLE 3

| | Present invention (V) | Conventional art 2 |
|---|---|---|
| Selected word line | V_{PGM} | V_{PGM} |
| Unselected word line | V_{PASS} | V_{PASS} |
| Selected bit line | 0 | 0 |
| Unselected bit line | V_{CC} | V_{CC} |
| String selection line | V_{CC} | V_{CC} |
| Ground selection line | 0~−V_{CC} | 0 |
| Common source line | 1.5 | 1.5 |
| Semiconductor layer | 1.5 | 0 |

According to another embodiment of the present invention, the NAND flash memory device may be configured to cut off the leakage current caused by self-boosting through the application of one of a ground voltage and a predetermined positive voltage to the common source line CSL. In detail, when a predetermined memory cell is programmed, the device may be configured to have voltage applied to the common source line CSL that has a magnitude corresponding to the voltage boost amount of an unselected region, e.g., about 1.5 V, as shown in Table 3.

TABLE 4

| | Present invention | Conventional art |
|---|---|---|
| Selected word line | 0 | 0 |
| Unselected word line | Floating | Floating |
| Selected bit line | Floating | Floating |
| Unselected bit line | — | — |
| String selection line | Floating | Floating |
| Ground selection line | Floating | Floating |
| Common source line | V_{ERS} | Floating |
| Semiconductor layer | V_{ERS} | V_{ERS} |

An erase operation of the NAND flash memory device may use FN-tunneling according to a voltage difference between a selected word line and a semiconductor layer. In order to prevent transistors selected by the selection lines from being damaged due to a high erase voltage applied to the semiconductor layer, a conventional erase operation may be performed while the string selection line, the ground selection line and the common source lines are in floating states, as shown in Table 4. In an embodiment of the present invention, the common source line CSL may be equipotential with the semiconductor layers 100 and 200. As shown in Table 4, an erase voltage V_{ERS} may be applied to the common source line CSL during the erase operation. However, the source regions 110S and 210S may not be damaged by the erase voltage V_{ERS}, since there is no potential difference between the common source line CSL and the semiconductor layers 100 and 200. Also, the erase operation according to the present invention may be performed in a state where the ground selection line GSL is floating, as shown in Table 4 and as done conventionally, so that the damage caused by an erase voltage applied to the common source line CSL and the semiconductor layer 100 and 200 may be prevented.

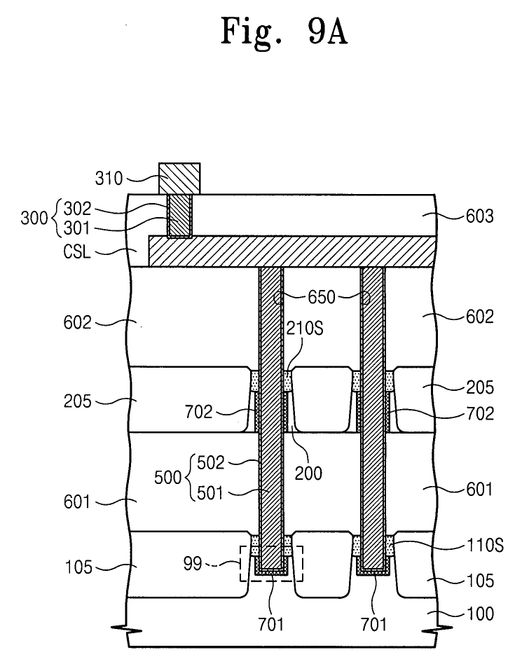

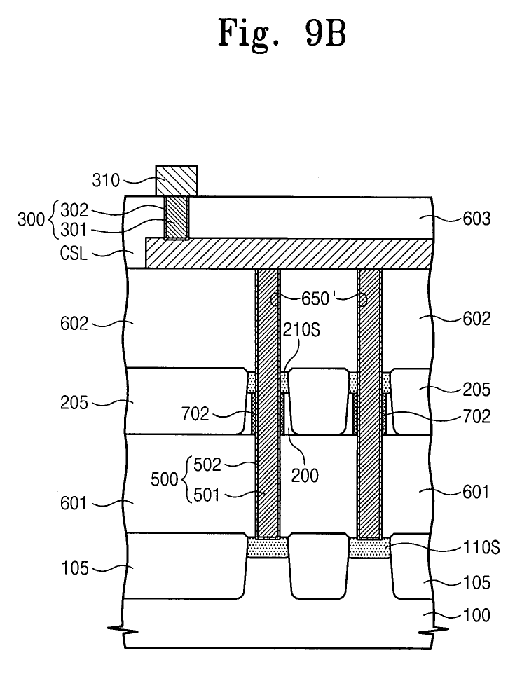

FIGS. 9A and 9B illustrate cross-sectional views of through-plug structures of a NAND flash memory device according to other embodiments of the present invention, which may include ohmic doped regions in the semiconductor layers 100 and 200. In other respects, these embodiments may be similar to the embodiments of the present invention that are described above. For clarity, in the following description, details of features that are substantially the same as those described above will not be repeated.

Referring to FIGS. 9A and 9B, first ohmic doped regions 701 contacting the respective source plugs 500 may be formed in the first semiconductor layer 100. The first ohmic doped regions 701 may provide ohmic contact between the source plug 500 and the first semiconductor layer 100, and may have the same conductivity type as that of the first semiconductor layer 100.

The source plug 500 may pass through first and second interlayer dielectric layers 601 and 602, and the second semiconductor layer 200, and may fill a through-hole 650 that exposes the first semiconductor layer 100. The first ohmic doped region 701 may be formed by, e.g., implanting impurities in surfaces of the first and second semiconductor layers 100 and 200 that are exposed through the through-hole 650, before the source plug 500 is formed. As illustrated in FIGS. 9A and 9B, the impurities may be implanted into inner walls of the semiconductor layer 200 to form second ohmic doped regions 702. The ohmic doped regions may be formed using, e.g., a general ion implantation technology.

In an embodiment, as illustrated in FIG. 9A, forming of the through-hole 650 may include recessing the first semiconductor layer 100 to a predetermined depth, in order to enhance electrical contact between the first semiconductor layer 100 and the source plug 500. The through-hole 650 may penetrate the first source region 110S of the first semiconductor layer 100, as indicated by the dashed box 99 in FIG. 9A. The first ohmic doped region 701 may extend to a predetermined depth in the first semiconductor layer 100.

According to another embodiment of the present invention, as illustrated in 9B, a through-hole 650′ may be formed to only expose the first source region 110S of the first semiconductor layer 100, without passing through the first source region 110S. In this case, the potential of the first semiconductor layer 100 may be controlled by a separate well-plug (not shown), and the first ohmic doped region 701 shown in FIG. 9A may be omitted. The second semiconductor layer 200 may include the second ohmic doped regions 702 shown in FIG. 9A.

The through-hole 650′ may be formed by, e.g., forming a preliminary through-hole passing through the second semiconductor layer 200 but not exposing the first semiconductor layer 100, and extending the preliminary through-hole to expose the first semiconductor layer 100. The second ohmic doped regions 702 may be selectively formed in the second semiconductor layer 200 exposed through the preliminary through-hole, before extending of the preliminary through-hole. Thus, impurities for the formation of the second ohmic doped regions 702 may not be implanted in the first source region 110S.

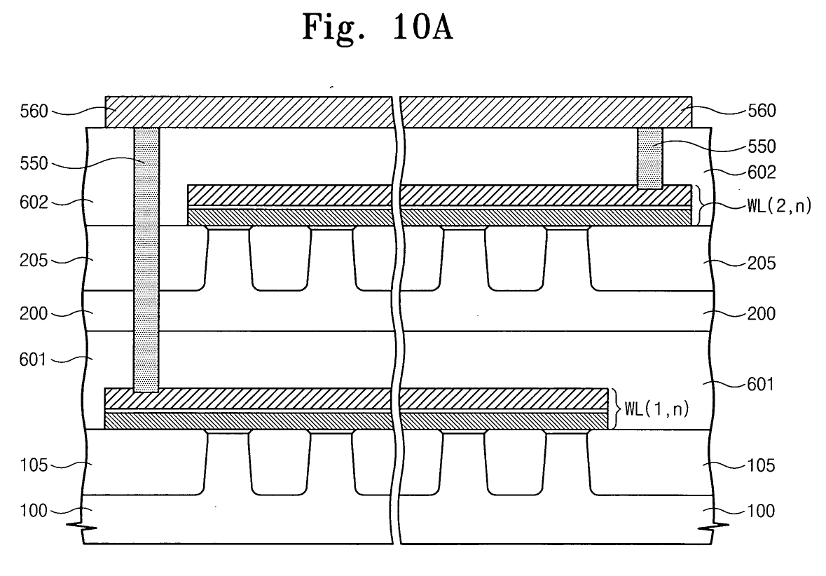

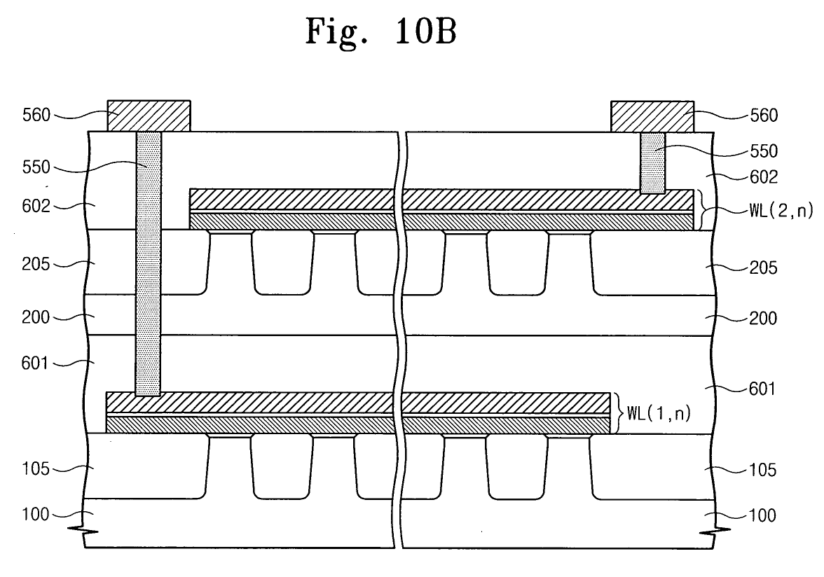

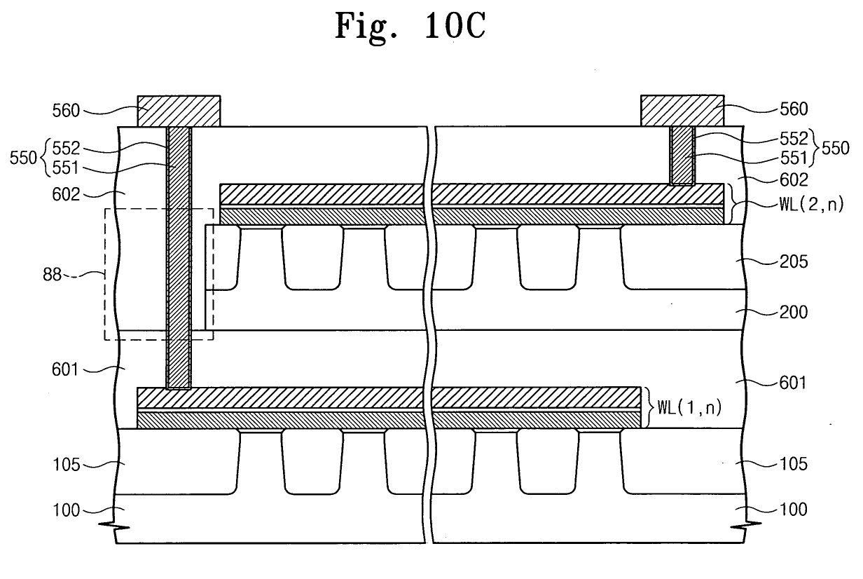

FIGS. 10A through 10C illustrate cross-sectional views of a NAND flash memory device according to additional embodiments of the present invention, which have a particular word line arrangement and features related to gate contact plugs connected to the word lines. In other respects, these embodiments may be similar to the embodiments of the present invention that are described above. For clarity, in the following description, details of features that are substantially the same as those described above will not be repeated.

Referring to FIGS. 10A and 10B, gate contact plugs 550 may be disposed on first word lines WL(1, n) on the first semiconductor layer 100, and on second word lines WL(2, n) on the second semiconductor layer 200. The second word lines WL(2, n) may be offset from the first word lines WL(1, n). The first and second word lines WL(1, n) and WL(2, n) may be offset by a predetermined distance in a longitudinal direction of the word lines WL. Thus, a portion of the second word lines WL(2, n) may not be disposed directly above the corresponding first word lines WL(1, n), so as to expose one set of ends of the first word lines WL(1, n). Thus, the gate contact plug 550 connected to the first word lines WL(1, n) may be spaced apart from the second word lines WL(2, n).

The gate contact plug 550 may penetrate the second semiconductor layer 200 to be connected to the first word lines WL(1, n). In order to prevent electric connection between the gate contact plug 550 and the second semiconductor layer 200, the gate contact plug 550 may be formed of silicon having a conductivity type different from that of the second semiconductor layer 200.

Gate lines 560 connected to the gate contact plug 550 may be disposed on the second interlayer dielectric layer 602. As illustrated in FIG. 10A, a first word line WL(1, n) and a second word line WL(2, n) that are stacked above one another may be connected to one gate line 560. Thus, the first and second word lines WL(1, n) and WL(2, n) may be equipotential. Independent selection transistors disposed at both sides of the first word lines WL(1, n) and the second word lines WL(2, n) may allow memory cells on the first and second semiconductor layers 100 and 200 to be independently controlled.

According to another embodiment of the present invention, as illustrated in FIG. 10B, the first word line WL(1, n) and the second word line WL(2, n) may be connected to different gate lines 560. Thus, memory cells on the first and second semiconductor layers 100 and 200 may be independently controlled. In another implementation (not shown), the stacked first and second word lines WL(1, n) and WL(2, n) may be connected to different gate lines 560, and those gate lines 560 may be connected together through another line, such that the stacked first and second word lines WL(1, n) and WL(2, n) may be equipotential.

Referring to FIG. 10C, the second semiconductor layer 200 may have an aperture on one set of ends of the word lines WL(1, n), as indicated by a dashed box 88 in FIG. 10C, such that gate contact plugs 550 connected to the word lines WL(1, n) may be separated from the second semiconductor layer 200. The aperture may be filled with another material, e.g., an insulating material. Since the gate contact plugs connected to the word lines WL(1, n) may be separated from the second semiconductor layer 200, the gate contact plugs 550 may respectively include a gate metal plug 551 and a gate barrier metal layer 552 that covers the gate metal plug 551. The gate barrier metal layer 552 may cover a lower surface and sidewalls of the gate metal plug 551. The gate metal plug 551 and the gate barrier metal layer 552 may be formed using, e.g., the same materials used for the metal plug 501 and the barrier metal layer 502 of the source plug 550, respectively.

In another, similar implementation, referring to FIGS. 2 and 4, where the active regions of the second semiconductor layer 200 are isolated by the device isolation layer patterns 205, the gate contact plugs 550 may include the gate metal plug 551 and the gate barrier metal layer 552, as described above in connection with FIG. 10C.

Embodiments of the present invention provide a semiconductor device in which source line plugs may include a metallic material having low resistivity. Accordingly, a semiconductor device according to embodiments of the present invention may exhibit enhanced operation speed, reduced power consumption, enhanced cell current, etc.

Embodiments of the present invention also provide a semiconductor device in which source line plugs may be electrically connected to semiconductor layers used as a well region, such that separate well plugs connected to well regions of a cell array may be unnecessary. In particular, as described above, even when a common source line and a well region are equipotential, a NAND flash memory device according to embodiments of the present invention may be programmed and erased normally. Consequently, embodiments of the present invention may enable manufacture of a 3-dimensional NAND flash memory device that operates normally, without an unduly complex manufacturing process and without necessitating separate well plugs and an attendant reduction in the degree of integration.

Exemplary embodiments of the present invention have been disclosed herein, and although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

What is claimed is:

1. A NAND flash memory device, comprising:
a plurality of stacked semiconductor layers;
device isolation layer patterns disposed in predetermined regions of each of the plurality of semiconductor layers, the device isolation layers defining active regions;
source and drain impurity regions in the active regions;
a source line plug structure electrically connecting the source impurity regions; and
a bit-line plug structure electrically connecting the drain impurity regions, wherein the source impurity regions are electrically connected to the semiconductor layers.

2. The device as claimed in claim 1, wherein the source line plug structure is in ohmic contact with the source impurity regions and at least one of the plurality of semiconductor layers.

3. The device as claimed in claim 1, wherein the source line plug structure includes at least one metallic material.

4. The device as claimed in claim 3, wherein the source line plug structure includes:
a metal plug passing through at least one of the plurality of semiconductor layers and at least one of the source impurity regions; and
a barrier metal layer formed at least at a sidewall of the metal plug, the barrier metal layer directly contacting the at least one semiconductor layer and the at least one source impurity region.

5. The device as claimed in claim 1, wherein the source line plug structure passes through at least one of the plurality semiconductor layers and at least one of the source impurity regions.

6. The device as claimed in claim 1, wherein the plurality of stacked semiconductor layers includes:
a lower semiconductor layer, the lower semiconductor layer being a single-crystalline semiconductor wafer; and
at least one upper semiconductor layer stacked on the lower semiconductor layer,
wherein the source line plug structure passes through the upper semiconductor layer and source impurity regions of the upper semiconductor layer, the source line plug structure being connected to source impurity regions of the lower semiconductor layer.

7. The device as claimed in claim 6, wherein the source line plug structure passes through the source impurity regions of the lower semiconductor layer and is electrically connected to the lower semiconductor layer.

8. The device as claimed in claim 7, further comprising an ohmic doped region disposed under the source impurity region of the lower semiconductor layer such that the lower semiconductor layer and the source line plug structure are in ohmic contact, wherein the ohmic doped region has a different conductivity type from that of the source and drain impurity regions.

9. The device as claimed in claim 6, wherein the bit-line plug structure passes through the upper semiconductor layer and the drain impurity regions of the upper semiconductor layer and is connected to the drain impurity regions of the lower semiconductor layer, and
the bit-line plug structure is formed of silicon having a conductivity type that is the same as that of the source and drain impurity regions and different from that of the semiconductor layers.

10. The device as claimed in claim 6, wherein a device isolation layer pattern in the upper semiconductor layer passes through the upper semiconductor layer.

11. The device as claimed in claim 1, further comprising:
a gate structure disposed between the bit-line plug structure and the source line plug structure, the gate structure crossing the active regions of each of the semiconductor layers;
bit lines crossing the gate structure, the bit lines connected to the drain impurity regions by the bit-line plug structure; and
a common source line connected to the source impurity regions by the source line plug structure, wherein the gate structure includes:
a string selection line adjacent to the bit-line plug structure;
a ground selection line adjacent to the source line plug structure; and
a plurality of word lines between the string selection line and the ground selection line.

12. The device as claimed in claim 11, wherein the device is configured to program a memory cell selected by a predetermined bit line and a predetermined word line of a predetermined semiconductor layer by applying one of a ground voltage and a positive power voltage to the common source line.

13. The device as claimed in claim 12, wherein the device is further configured to program the selected memory cell by applying an accumulation voltage to the ground selection line, the accumulation voltage allowing an active region under the ground selection line to be in an accumulation state.

14. The device as claimed in claim 13, wherein the accumulation voltage is within a range of about a negative power voltage to about 0 volts.

15. The device as claimed in claim 11, wherein the device is configured to erase a memory cell of a predetermined semiconductor layer by applying an erase voltage to the common source line.

16. The device as claimed in claim 11, wherein the plurality of stacked semiconductor layers includes a lower semiconductor layer and an upper semiconductor layer that are sequentially stacked,
the gate structure includes lower word lines and upper word lines disposed on the lower and upper semiconductor layers, respectively,
lower gate contact plugs and upper gate contact plugs are connected to the lower and upper word lines, respectively, and
the upper word lines are offset from the lower word lines, such that the lower gate contact plug is separated from the upper word lines.

17. The device as claimed in claim 16, wherein the upper semiconductor layer has a gate aperture passing through the upper semiconductor layer, wherein the gate aperture includes a region in which the lower gate contact plug is disposed.

18. The device as claimed in claim 17, wherein the lower and upper gate contact plugs include at least one metallic material.

19. The device as claimed in claim 16, wherein the lower and upper gate contact plugs are silicon having a different conductivity type from that of the source and drain impurity regions.

20. The device as claimed in claim 16, wherein a lower word line and an upper word line are equipotential during operation of the device.

21. The device as claimed in claim 1, wherein the bit-line plug structure is silicon having a conductivity type that is the same as that of the impurity regions and different from that of the semiconductor layers.

22. The device as claimed in claim 1, further comprising an ohmic doped region in at least one of the semiconductor layers, the ohmic doped region electrically contacting the source line plug structure and having a different conductivity type from that of the source and drain impurity regions.

23. The device as claimed in claim 1, wherein the source impurity regions are equipotential with the semiconductor layers during operation of the device.
